(19) United States
(12) Patent Application Publication
(10) Pub. No.: US 2025/0366379 A1
(43) Pub. Date: Nov. 27, 2025

(54) SEMICONDUCTOR MEMORY DEVICE HAVING VARIABLE RESISTANCE LAYERS

(71) Applicant: SK hynix Inc., Icheon-si (KR)

(72) Inventor: Jung Nam KIM, Icheon-si (KR)

(21) Appl. No.: 19/034,257

(22) Filed: Jan. 22, 2025

(30) Foreign Application Priority Data
May 21, 2024 (KR) 10-2024-0065698

(51) Int. Cl. H10N 70/00; H10B 63/00; H10N 70/20

(52) U.S. Cl. CPC H10N 70/828; H10B 63/80; H10N 70/066; H10N 70/24; H10N 70/8265

(57) ABSTRACT

A semiconductor memory device includes: a lower interconnection line; a lower electrode over the lower interconnection line; a variable resistance layer over the lower electrode; an oxygen reservoir layer over the variable resistance layer; an upper electrode over the oxygen reservoir layer; and an upper interconnection line over the upper electrode, wherein the variable resistance layer includes: a plurality of switching patterns spaced apart from each other in a horizontal direction; and an isolating dielectric layer filling spaces between the switching patterns. Each of the switching patterns includes an upper portion having a first width and a lower portion having a second width, and the first width is greater than the second width.

### CROSS-REFERENCE TO RELATED APPLICATION

The present application claims priority under 35 U.S.C § 119(a) to Korean Patent Application No. 10-2024-0065698, filed on May 21, 2024, in the Korean Intellectual Property Office, which is incorporated herein by reference in its entirety.

### BACKGROUND

### 1. Field

Embodiments of the present disclosure relate to a semiconductor memory device having variable resistance layers.

### 2. Description of the Related Art

Disclosed is a semiconductor memory device capable of storing data by using a variable resistance layer having a property of switching between different resistance states according to a voltage or current.

### SUMMARY

Embodiments of the present disclosure are directed to a semiconductor memory device having variable resistance layers.

Embodiments of the present disclosure are directed to a method for fabricating a semiconductor memory device having variable resistance layers.

In accordance with an embodiment of the present disclosure, a semiconductor memory device includes: a lower interconnection line; a lower electrode over the lower interconnection line; a variable resistance layer over the lower electrode; an oxygen reservoir layer over the variable resistance layer; an upper electrode over the oxygen reservoir layer; and an upper interconnection line over the upper electrode, wherein the variable resistance layer includes: a plurality of switching patterns spaced apart from each other in a horizontal direction; and an isolating dielectric layer filling spaces between switching patterns. Each of the plurality of switching patterns includes an upper portion having a first width and a lower portion having a second width, and the first width is greater than the second width.

In accordance with another embodiment of the present disclosure, a method for fabricating a semiconductor memory device includes: forming a lower electrode material layer; forming an isolating dielectric material layer over the lower electrode material layer, the isolating dielectric material layer including a plurality of pin holes each having an average pin hold width; forming a plurality of wide holes each having an average wide hole width by widening the pin holes; forming a variable resistance material layer by forming a plurality of switching patterns in the plurality of wide holes, the variable resistance material layer including the plurality of switching patterns and an isolating dielectric layer surrounding side surfaces of the plurality of switching patterns; forming an oxygen reservoir material layer over the variable resistance material layer; forming an upper electrode material layer over the oxygen reservoir material layer; and forming an upper electrode, an oxygen reservoir layer, a variable resistance layer, and a lower electrode by patterning the upper electrode material layer, the oxygen reservoir material layer, the variable resistance material layer, and the lower electrode material layer.

### BRIEF DESCRIPTION OF THE DRAWINGS

FIG. 1A is a schematic circuit diagram of a semiconductor memory device in accordance with an embodiment of the present disclosure.

FIG. 1B is a perspective view of a semiconductor memory device in accordance with an embodiment of the present disclosure.

FIGS. 2A to 2D schematically illustrate cross-sections of semiconductor memory devices taken along a line I-I′ shown in FIG. 1 in accordance with embodiments of the present disclosure.

FIGS. 3A and 3B are enlarged views illustrating an area A shown in FIG. 2A.

FIGS. 4 to 18 are longitudinal cross-sectional views illustrating methods for fabricating semiconductor memory devices in accordance with embodiments of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

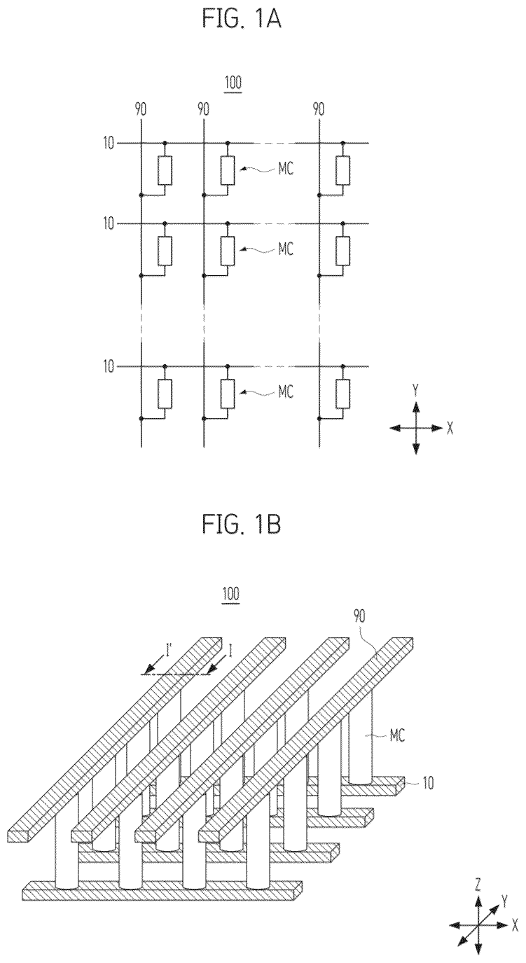

FIG. 1A is a schematic circuit diagram of a semiconductor memory device in accordance with an embodiment of the present disclosure. FIG. 1B is a perspective view of a semiconductor memory device in accordance with an embodiment of the present disclosure. Referring to FIGS. 1A and 1B, a semiconductor memory device 100 may include lower interconnection lines 10, upper interconnection lines 90, and memory cell structures MC. The lower interconnection lines 10 may extend parallel to each other in a first horizontal direction X. The lower interconnection lines 10 may be word lines. The upper interconnection lines 90 may extend parallel to each other in a second horizontal direction Y. The upper interconnection lines 90 may be bit lines. In other embodiments, the lower interconnection lines 10 may be bit lines, and the upper interconnection lines 90 may be word lines. The first horizontal direction X and the second horizontal direction Y may be perpendicular to each other.

The memory cell structures MC may be disposed at the intersections between the lower interconnection lines 10 and the upper interconnection lines 90, respectively. Each of the memory cell structures MC may have a vertical pillar shape. Each of the memory cell structures MC may include a variable resistance layer. Conductive filaments may be formed or disconnected in the variable resistance layer according to a voltage or current. Each of the memory cell structures MC may be a two-pole device. That is, each of the memory cell structures MC may include two electrodes. First electrodes of the memory cell structures MC may be electrically connected to the lower interconnection lines 10, respectively, and second electrodes of the memory cell structures MC may be electrically connected to the upper interconnection lines 90, respectively.

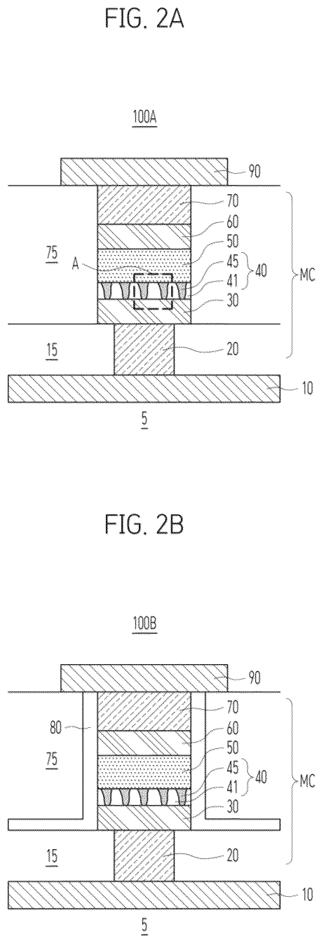

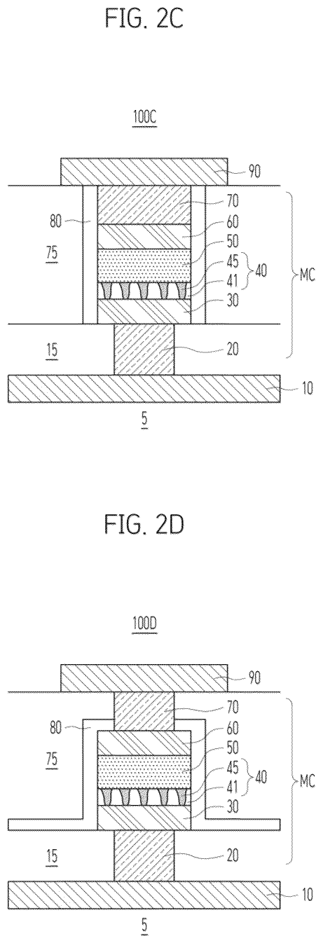

FIGS. 2A to 2D schematically illustrate cross-sections of semiconductor memory devices taken along a line I-I′ shown in FIG. 1 in accordance with embodiments of the present disclosure. Referring to FIG. 2A, a semiconductor memory device 100A may include a lower interconnection line 10, a memory cell structure MC, and an upper interconnection line 90 that are sequentially disposed in a vertical direction over an underlying layer 5. The memory cell structure MC may include a lower contact plug 20, a lower electrode 30, a variable resistance layer 40, an oxygen reservoir layer 50, an upper electrode 60, and an upper contact plug 70. The variable resistance layer 40 may include an isolating dielectric layer 41 and switching patterns 45. The semiconductor memory device 100A may further include a lower inter-layer dielectric layer 15 and an upper inter-layer dielectric layer 75 that surround side surfaces of each memory cell structure MC.

The underlying layer 5 may include a substrate, or a dielectric layer disposed over the substrate. In an embodiment, the underlying layer 5 may include one among a silicon wafer, an epitaxially grown single crystalline silicon layer, a silicon compound layer such as a silicon germanium compound, and a compound semiconductor layer such as a gallium arsenide layer and an aluminum gallium arsenide layer. In an embodiment, the underlying layer 5 may include at least one of a silicon oxide layer, a silicon nitride layer, or other silicon-based dielectric layer.

The lower interconnection line 10 may be disposed over the underlying layer 5. The lower interconnection line 10 may include a metal such as tungsten, a metal nitride such as titanium nitride, a metal silicide, a metal alloy, or other conductive materials.

The lower contact plug 20 may be disposed between the lower interconnection line 10 and the lower electrode 30. The lower contact plug 20 may electrically connect the lower interconnection line 10 to the lower electrode 30. The lower contact plug 20 may include at least one among doped polycrystalline silicon, metals, metal alloys, metal compounds, and metal silicides. In an embodiment, the lower contact plug 20 may include tungsten or titanium nitride.

The lower inter-layer dielectric layer 15 may be disposed on an upper surface of the lower interconnection line 10 and surround side surfaces of the lower contact plug 20. An upper surface of the lower inter-layer dielectric layer 15 and an upper surface of the lower contact plug 20 may be co-planar. The lower inter-layer dielectric layer 15 may include a dielectric material, such as silicon oxide.

The lower electrode 30 may be disposed over the lower contact plug 20 and the lower inter-layer dielectric layer 15. The lower electrode 30 may include a diffusion barrier layer for blocking diffusion of oxygen atoms or oxygen ions. The lower electrode 30 may include a metal nitride, such as titanium nitride.

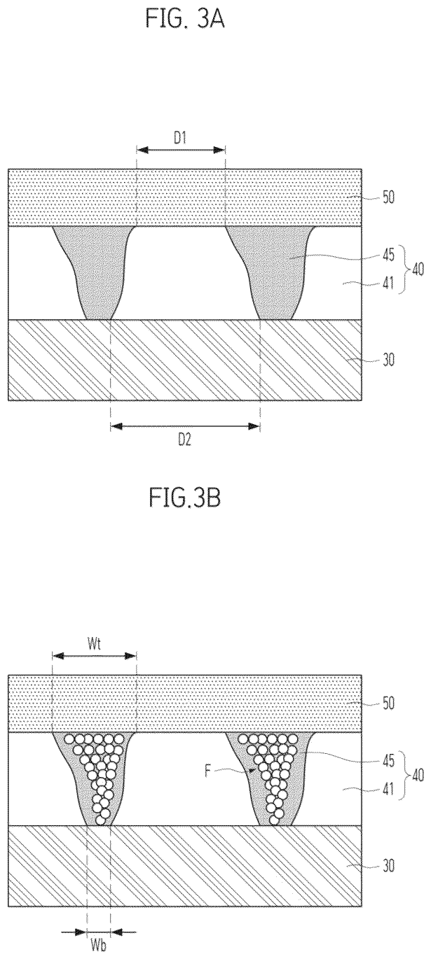

The variable resistance layer 40 may be disposed over the lower electrode 30. The variable resistance layer 40 will be described in more detail with reference to FIGS. 3A and 3B.

The oxygen reservoir layer 50 may be disposed over the variable resistance layer 40. The oxygen reservoir layer 50 may include tantalum oxide. The oxygen reservoir layer 50 may provide oxygen atoms or oxygen ions to the variable resistance layer 40. The oxygen reservoir layer 50 may absorb oxygen atoms or oxygen ions from the variable resistance layer 40.

The upper electrode 60 may include a diffusion barrier layer for blocking the diffusion of oxygen atoms or oxygen ions. The upper electrode 60 may include a metal nitride, such as titanium nitride.

The side surfaces of the lower electrode 30, the variable resistance layer 40, the oxygen reservoir layer 50, and the upper electrode 60 may be vertically aligned with each other and side surfaces may be vertically aligned or co-planar.

The upper contact plug 70 may be disposed between the upper electrode 60 and the upper interconnection line 90. The upper contact plug 70 may electrically connect the upper electrode 60 to the upper interconnection line 90. The upper contact plug 70 may include at least one among doped polycrystalline silicon, metals, metal alloys, metal compounds, and metal silicides. The upper contact plug 70 may include tungsten or titanium nitride. The side surfaces of the upper contact plug 70 may be vertically aligned with the side surfaces of the upper electrode 60 and may be vertically co-planar.

The upper inter-layer dielectric layer 75 may be disposed over the lower inter-layer dielectric layer 15 to surround side surfaces of the lower electrode 30, the variable resistance layer 40, the oxygen reservoir layer 50, the upper electrode 60, and the upper contact plug 70. An upper surface of the upper inter-layer dielectric layer 75 and an upper surface of the upper contact plug 70 may be co-planar. The upper inter-layer dielectric layer 75 may include a dielectric material, such as silicon oxide.

The upper interconnection line 90 may be disposed over the upper contact plug 70. The upper interconnection line 90 may include a metal such as tungsten, a metal nitride such as titanium nitride, a metal silicide, an alloy, or other conductive material.

Referring to FIGS. 2B to 2D, semiconductor memory devices 100B, 100C, and 100D may each further include a spacer 80 compared with the semiconductor memory device 100A illustrated in FIG. 2A.

Referring to FIG. 2B, the spacer 80 of the semiconductor memory device 100B may be conformally disposed on the upper surface of the lower inter-layer dielectric layer 15, and on the side surfaces of the lower electrode 30, the variable resistance layer 40, the oxygen reservoir layer 50, the upper electrode 60, and the upper contact plug 70. The spacer 80 may in effect separate and space apart the upper inter-layer dielectric layer 75 from the lower inter-layer dielectric layer 15, the lower electrode 30, the variable resistance layer 40, the oxygen reservoir layer 50, the upper electrode 60, and the upper contact plug 70. The spacer 80 may include an insulator that does not contain oxygen. For example, the spacer 80 may include silicon nitride-based insulators, such as one from among silicon nitride, silicon boron nitride, and silicon carbon nitride. The spacer 80 may block the migration and diffusion of oxygen atoms or oxygen ions.

Referring to FIG. 2C, the spacer 80 of the semiconductor memory device 100C may be conformally disposed on the side surfaces of the lower electrode 30, the variable resistance layer 40, the oxygen reservoir layer 50, the upper electrode 60, and the upper contact plug 70. The spacer 80 may be disposed over portions of the upper surface of the lower inter-layer dielectric layer 15.

Referring to FIG. 2D, the spacer 80 of the semiconductor memory device 100D may be conformally disposed on the upper surface of the lower inter-layer dielectric layer 15, on the side surfaces of the lower electrode 30, the variable resistance layer 40, the oxygen reservoir layer 50, and the upper electrode 60, and over portions of the upper surface of the upper electrode 60. The upper contact plug 70 may vertically pass through a portion of the upper inter-layer dielectric layer 75 and a portion of the spacer 80 to contact the upper electrode 60. The width of the upper contact plug 70 may be smaller than the width of the upper electrode 60.

FIGS. 3A and 3B are enlarged views illustrating an area A of FIG. 2A. Referring to FIGS. 3A and 3B, the variable resistance layer 40 may include an isolating dielectric layer 41 and switching patterns 45. The isolating dielectric layer 41 may surround the side surfaces of the switching patterns 45. The isolating dielectric layer 41 may fill spaces between the switching patterns 45. As oxygen vacancies migrate in the switching patterns 45, a conductive path, i.e., a conductive filament F, may be formed. The isolating dielectric layer 41 may block the migration and diffusion of the oxygen vacancies between the switching patterns 45. The isolating dielectric layer 41 may include an insulator that does not contain oxygen. For example, the isolating dielectric layer 41 may include at least one among a silicon nitride-based insulator, such as silicon nitride, silicon boron nitride, and silicon carbon nitride.

The switching patterns 45 may be disposed to be spaced apart from each other in the horizontal direction. The lower ends of the switching patterns 45 may be in contact with the lower electrode 30. The upper ends of the switching patterns 45 may be in contact with the oxygen reservoir layer 50. The switching patterns 45 may be spaced apart from each other by the isolating dielectric layer 41. In cross-section, the switching patterns 45 may have an inverted triangle shape or an inverted trapezoid shape. A width Wt of an upper portion of the switching patterns 45 may be greater than a width Wb of a lower portion of the switching patterns 45. Accordingly, a distance D1 between the upper ends of the switching patterns 45 adjacent to the oxygen reservoir layer 50 may be smaller than a distance D2 between the lower ends of the switching patterns 45 adjacent to the lower electrode 30. The shape of the switching patterns 45 may be similar to the shape of the conductive filaments F that are formed as the oxygen vacancies migrate from the oxygen reservoir layer 50 to the lower electrode 30. Therefore, the conductive filament F formed by the oxygen vacancies may be formed in a stable shape.

The switching patterns 45 may include a transition metal oxide. For example, the switching patterns 45 may include at least one among titanium oxide, vanadium oxide, manganese oxide, iron oxide, cobalt oxide, zinc oxide, yttrium oxide, zirconium oxide, niobium oxide, molybdenum oxide, ruthenium oxide, palladium oxide, barium oxide, lanthanum oxide, hafnium oxide, iridium oxide, and other transition metal oxides.

When a set voltage is applied between the upper electrode 60 and the lower electrode 30, electrical paths, for example, conductive filaments F, may be formed by the migration of oxygen vacancies in the switching patterns 45. The oxygen reservoir layer 50 may absorb oxygen atoms or oxygen ions from the switching patterns 45 as conductive filaments F are formed in the switching patterns 45. The switching patterns 45 may transition to a low resistance state.

When a reset voltage opposite to the set voltage is applied between the upper electrode 60 and the lower electrode 30, the oxygen reservoir layer 50 may provide oxygen atoms or oxygen ions to the switching patterns 45, thereby reducing the oxygen vacancies in the switching patterns 45. The conductive filaments F may be disconnected due to the lack of oxygen vacancies in the switching patterns 45. The switching patterns 45 may transition to a high resistance state.

The switching patterns 45 and the isolating dielectric layer 41 may be directly in contact with the lower electrode 30. The switching patterns 45 and the isolating dielectric layer 41 may directly contact the oxygen reservoir layer 50.

According to the technological concepts of the present disclosure, the isolating dielectric layer 41 may block the horizontal migration and diffusion of the oxygen vacancies between the switching patterns 45. By reducing the contact area between the switching patterns 45 and the lower electrode 30, spacing distances between the lower portions of the switching patterns 45 may be increased. Compared to a semiconductor device including only a single non-separated variable resistance layer, in embodiments of the disclosure, the conductive filaments F of the switching patterns 45 may start to be formed at a relatively lower set voltage. As a result, conductive filaments F having a smaller width may be formed. The width of a conductive filament F that starts to be formed at the relatively lower set voltage may be easily adjusted according to the applied set voltage. As a result, the number of electrical resistance states that may be realized may increase in proportion to the variations in the width of the conductive filaments F. Also, the switching speed and switching stability of the semiconductor memory devices 100A to 100D may be improved and, the data retention among the switching patterns 45 may also be improved.

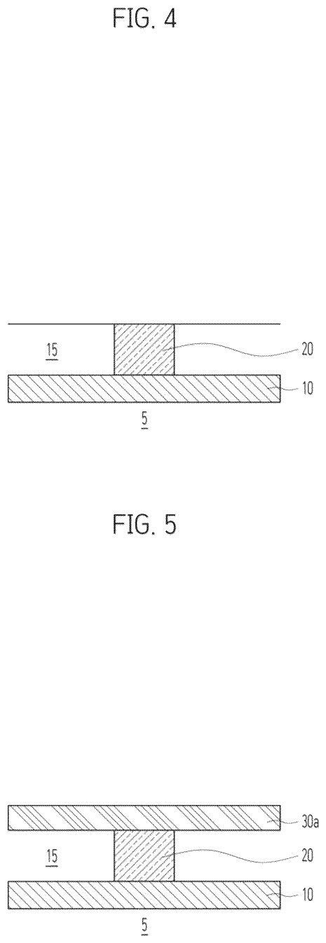

FIGS. 4 to 18 are longitudinal cross-sectional views illustrating methods for fabricating semiconductor memory devices in accordance with embodiments of the present disclosure. Referring to FIG. 4, methods may include forming a lower interconnection line 10, a lower inter-layer dielectric layer 15, and a lower contact plug 20 over an underlying layer 5. Forming the lower interconnection line 10 may include depositing a lower interconnection line material layer over the underlying layer 5, and performing a photolithography process and a patterning process to form a plurality of conductive interconnections extending in a horizontal direction. Forming the lower inter-layer dielectric layer 15 may include forming a dielectric layer, such as a silicon oxide layer, over the lower interconnection line 10 by performing a deposition process, such as a Chemical Vapor Deposition (CVD) process. Forming the lower contact plug 20 may include forming a contact hole that vertically penetrates the lower inter-layer dielectric layer 15 to expose the lower interconnection line 10, and filling the inside of the contact hole with a conductor. The method may further include performing a planarization process, such as a Chemical Mechanical Polishing (CMP) process, to co-planarize the upper surface of the lower contact plug 20 and the upper surface of the lower inter-layer dielectric layer 15.

Referring to FIG. 5, methods may further include forming a lower electrode material layer 30a over the lower contact plug 20 and the lower inter-layer dielectric layer 15. Forming the lower electrode material layer 30a may include forming a metal layer or a metal nitride layer by performing a deposition process, such as a Chemical Vapor Deposition (CVD) process. The lower electrode material layer 30a may include a diffusion barrier layer for blocking diffusion of oxygen atoms or oxygen ions. For example, the lower electrode material layer 30a may include a metal nitride, such as titanium nitride (TiN).

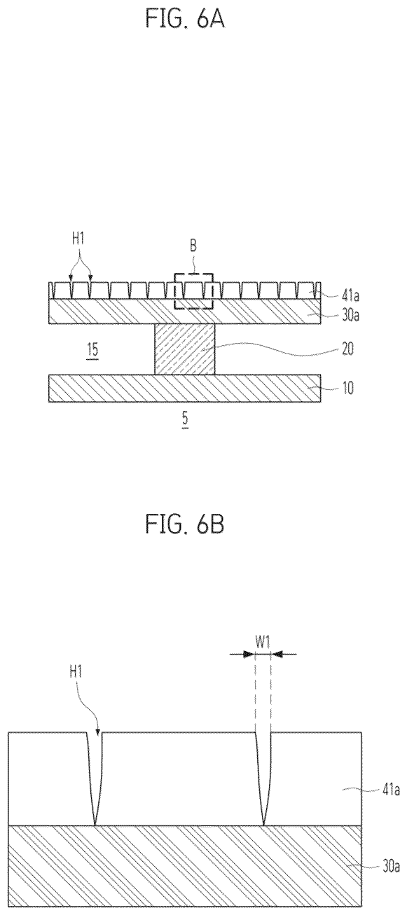

Referring to FIGS. 6A and 6B, methods may further include forming an isolating dielectric material layer 41a over the lower electrode material layer 30a. FIG. 6B is an enlarged view of an area B shown in FIG. 6A. The isolating dielectric material layer 41a may include a plurality of pin holes H1. The pin holes H1 may be randomly formed in the isolating dielectric material layer 41a. The pin holes H1 may vertically penetrate the isolating dielectric material layer 41a. Some of the pin holes H1 may expose the surface of the lower electrode material layer 30a. Other some of the pin holes H1 may not expose the lower electrode material layer 30a. The bottom surfaces of the other some of the pin holes H1 may be disposed in the isolating dielectric material layer 41a. The pin holes H1 may be formed and distributed to have an average first width W1. The first width W1 may be as small as several angstroms (Å) to several nanometers (nm).

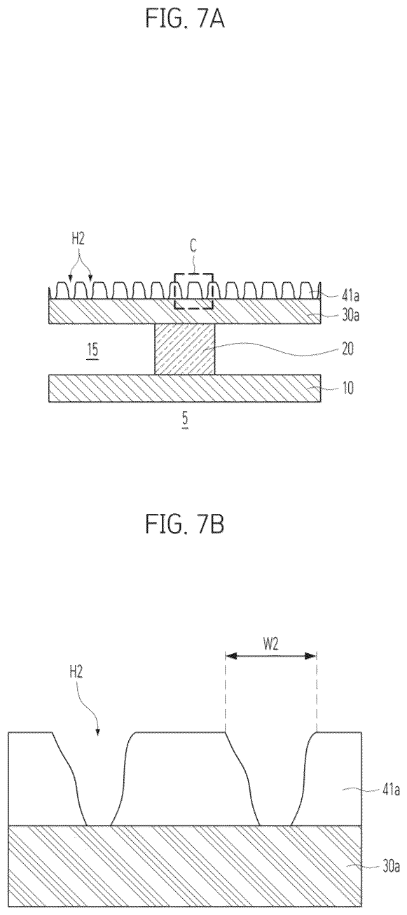

Referring to FIGS. 7A and 7B, methods may further include performing a widening process to widen the width of the pin holes H1 shown in FIG. 6A. FIG. 7B is an enlarged view of an area C shown in FIG. 7A. The pin holes H1 of FIG. 6A may be expanded into wide holes H2 having an average second width W2. The second width W2 may be greater than the first width W1 of FIG. 6B. The second width W2 may range from tens of nanometers (nm) to several micrometers (μm). The widening process may include performing a process from among a dry etching process and a wet etching process, for example. The wide holes H2 may include a lower region having a relatively smaller diameter and an upper region having a relatively larger diameter. The diameter of the wide holes H2 may become smaller in a downward vertical direction and become larger in an upward vertical direction. The lower electrode material layer 30a may be exposed at the bottom of wide holes H2.

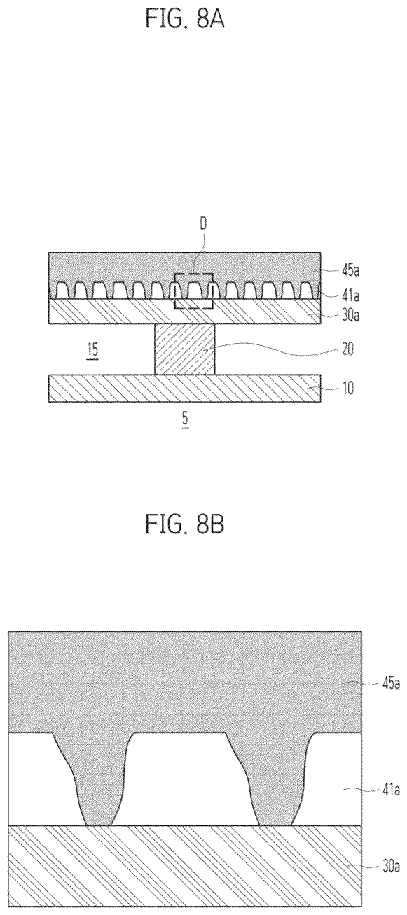

Referring to FIGS. 8A and 8B, methods may include forming a switching material layer 45a over the isolating dielectric material layer 41a by performing a deposition process, such as a Chemical Vapor Deposition (CVD) process. FIG. 8B is an enlarged view of an area D shown in FIG. 8A. The switching material layer 45a may completely fill the wide holes H2 and contact the lower electrode material layer 30a. The switching material layer 45a may include a transition metal oxide. For example, the switching material layer 45a may include at least one among titanium oxide, vanadium oxide, manganese oxide, iron oxide, cobalt oxide, zinc oxide, yttrium oxide, zirconium oxide, niobium oxide, molybdenum oxide, ruthenium oxide, palladium oxide, barium oxide, lanthanum oxide, hafnium oxide, iridium oxide, and other transition metal oxides.

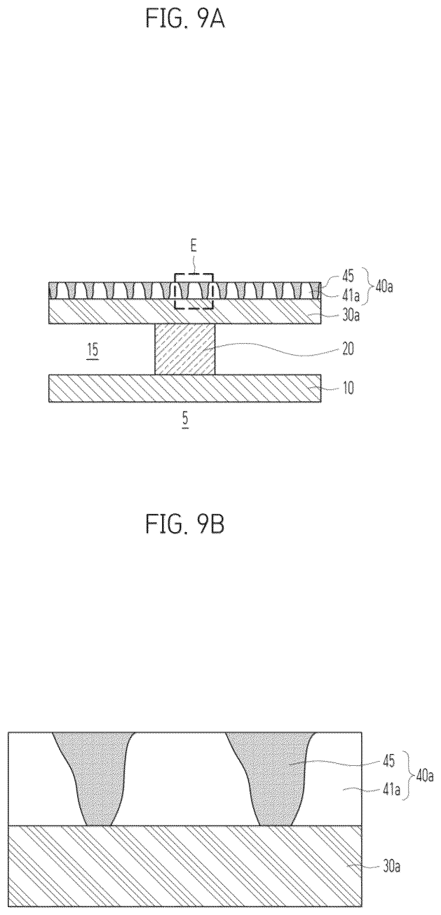

Referring to FIGS. 9A and 9B, methods may further include performing a planarization process to remove an upper portion of the switching material layer 45a and form a variable resistance material layer 40a. FIG. 9B is an enlarged view of an area E shown in FIG. 9A. The variable resistance material layer 40a may include an isolating dielectric material layer 41a and switching patterns 45. The upper surfaces of the isolating dielectric material layer 41a may be exposed through the planarization process. The switching material layer 45a in the wide holes H2 of FIGS. 8A and 8B are retained in the variable resistance material layer 40a to form a plurality of switching patterns 45. The upper surfaces of the switching patterns 45 and the upper surfaces of the isolating dielectric material layer 41a may be co-planar. The planarization process may include an etch-back process or a Chemical Mechanical Polishing (CMP) process.

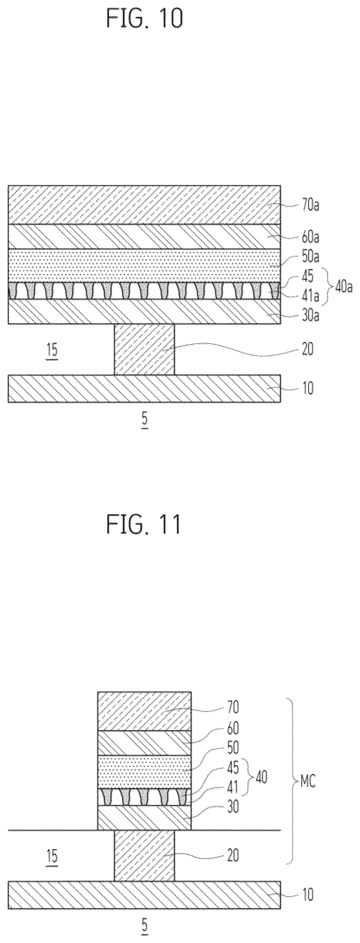

Referring to FIG. 10, methods may further include forming an oxygen reservoir material layer 50a over the variable resistance material layer 40a by performing a deposition process, forming an upper electrode material layer 60a over the oxygen reservoir material layer 50a, and forming an upper contact plug material layer 70a over the upper electrode material layer 60a. The oxygen reservoir material layer 50a may include tantalum oxide. The upper electrode material layer 60a may include a metal nitride, such as titanium nitride. The upper contact plug material layer 70a may include a metal, such as tungsten, or a metal nitride, such as titanium nitride.

Referring to FIG. 11, methods may further include forming a memory cell structure MC by patterning the upper contact plug material layer 70a, the upper electrode material layer 60a, the oxygen reservoir material layer 50a, the variable resistance material layer 40a, and the lower electrode material layer 30a. The memory cell structure MC may include a lower contact plug 20, a lower electrode 30, a variable resistance layer 40, an oxygen reservoir layer 50, an upper electrode 60, and an upper contact plug 70.

Subsequently, referring again to FIG. 2A, methods may further include forming an upper inter-layer dielectric layer 75 surrounding the side surfaces of the lower electrode 30, the variable resistance layer 40, the oxygen reservoir layer 50, the upper electrode 60, and the upper contact plug 70, and forming an upper interconnection line 90 over the upper contact plug 70 and the upper inter-layer dielectric layer 75. Forming the upper inter-layer dielectric layer 75 may include performing a deposition process and a planarization process. The upper surface of the upper contact plug 70 may be exposed. The upper surface of the upper contact plug 70 and the upper surface of the upper inter-layer dielectric layer 75 may be co-planar. The upper inter-layer dielectric layer 75 may include silicon oxide. Forming the upper interconnection line 90 may include performing a deposition process, a photolithography process, and an etching process. The upper interconnection line 90 may include a metal such as tungsten, a metal nitride such as titanium nitride, a metal silicide, an alloy, or other conductive material.

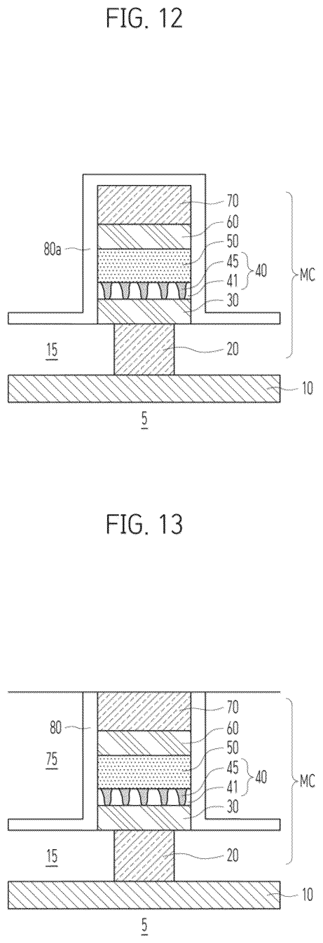

FIGS. 12 and 13 are longitudinal cross-sectional views illustrating methods for fabricating a semiconductor memory device in accordance with embodiments of the present disclosure. Referring to FIG. 12, methods may include performing the processes described above with reference to FIGS. 4 to 11, and further forming a spacer material layer 80a that covers the memory cell structure MC. The spacer material layer 80a may be conformally formed on the side surfaces and upper surface of the memory cell structure MC, and over the lower inter-layer dielectric layer 15. The spacer material layer 80a may include a dielectric layer, such as a silicon nitride layer.

Referring to FIG. 13, methods may include forming an upper inter-layer dielectric layer 75 that covers the memory cell structure MC and the spacer material layer 80a, and performing a planarization process to expose the upper surface of the upper contact plug 70. Extra spacer material layer 80a on the upper surface of the memory cell structure MC may be removed. Accordingly, spacer material layer 80a may be used to form the spacer 80 conformally on the sidewalls of the memory cell structure MC and on the upper surface of the lower inter-layer dielectric layer 15. Subsequently, referring again to FIG. 2B, methods may further include forming the upper interconnection line 90 over the upper contact plug 70.

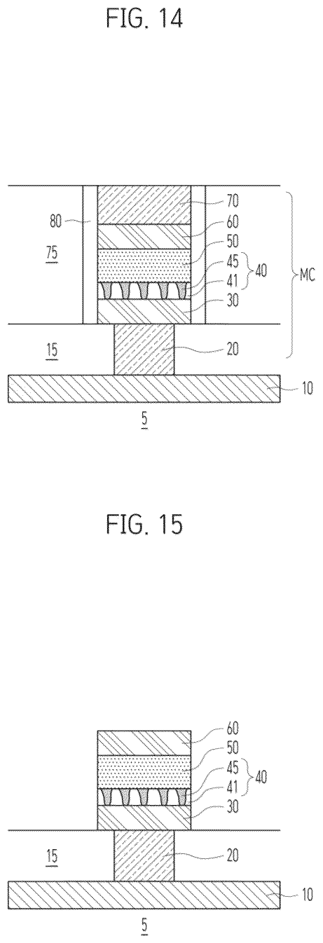

FIG. 14 is a longitudinal cross-sectional view illustrating methods for fabricating a semiconductor memory device in accordance with an embodiment of the present disclosure. Referring to FIG. 14, the method may include performing the processes described above with reference to FIGS. 4 to 12, and further forming a spacer 80 only on the sidewall of the memory cell structure MC by performing an etch-back process to expose portions of the lower inter-layer dielectric layer 15, forming an upper inter-layer dielectric layer 75 that covers the spacer material layer 80a, and performing a planarization process to expose the upper surface of the upper contact plug 70, which is co-planar with upper surfaces of upper inter-layer dielectric layer 75 and spacer 80. The upper surface of the upper contact plug 70 of the memory cell structure MC may be exposed. As a result of the etch-back process, most of the upper surface of the lower inter-layer dielectric layer 15 may be exposed without being covered by the spacer 80. Subsequently, referring again to FIG. 2C, the method may further include forming an upper interconnection line 90 over the upper contact plug 70.

FIGS. 15 to 21 are longitudinal cross-sectional views illustrating methods for fabricating semiconductor memory devices in accordance with embodiments of the present disclosure. Referring to FIG. 15, methods may include performing the processes described above with reference to FIGS. 4 to 9A and 9B, and further forming an oxygen reservoir material layer 50a that is disposed on a variable resistance material layer 40a, forming an upper electrode material layer 60a over the oxygen reservoir material layer 50a, and performing a patterning process to form a lower electrode 30, a variable resistance layer 40, an oxygen reservoir layer 50, and an upper electrode 60.

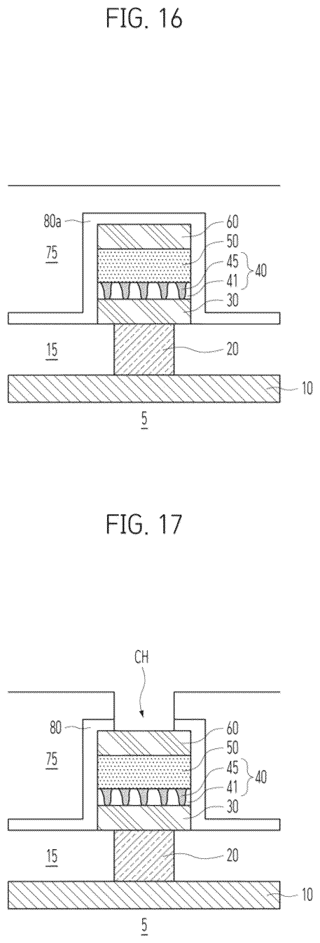

Referring to FIG. 16, methods may further include forming a spacer material layer 80a and forming an upper inter-layer dielectric layer 75. The spacer material layer 80a may be conformally formed on the upper surface of the lower inter-layer dielectric layer 15, the side surfaces of the lower electrode 30, the variable resistance layer 40, the oxygen reservoir layer 50, and the upper electrode 60, and the upper surface of the upper electrode 60. The upper inter-layer dielectric layer 75 may cover the spacer material layer 80a.

Referring to FIG. 17, methods may further include forming a contact hole CH that penetrates the upper inter-layer dielectric layer 75 and the spacer material layer 80a to expose the upper surface of the upper electrode 60. The spacer material layer 80a may be used to form as a spacer 80 that exposes a portion of the upper surface of the upper electrode 60.

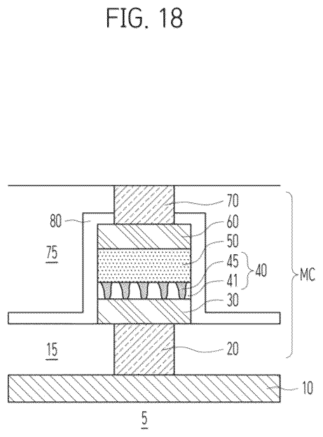

Referring to FIG. 18, methods may further include forming an upper contact plug 70 by filling the contact hole CH with a conductor. The upper surface of the upper contact plug 70 and the upper surface of the upper inter-layer dielectric layer 75 may be subject to a planarization process to become co-planar. Subsequently, referring again to FIG. 2D, methods may further include forming an upper interconnection line 90 over the upper contact plug 70.

According to embodiments of the present disclosure, it is possible to secure improved switching rate and switching stability of a semiconductor memory device.

According to embodiments of the present disclosure, deterioration of data retention may be improved by reducing deleterious effects between the switching patterns of a semiconductor memory device.

While the present disclosure has been described with respect to some specific embodiments, it will be apparent to those skilled in the art that various changes and modifications may be made without departing from the spirit and scope of the disclosure as defined in the following claims.

What is claimed is:

1. A semiconductor memory device, comprising:
a lower interconnection line;
a lower electrode over the lower interconnection line;
a variable resistance layer over the lower electrode;
an oxygen reservoir layer over the variable resistance layer;
an upper electrode over the oxygen reservoir layer; and
an upper interconnection line over the upper electrode,
wherein the variable resistance layer includes:
a plurality of switching patterns spaced apart from each other in a horizontal direction; and
an isolating dielectric layer filling spaces between the plurality of switching patterns,
wherein each of the plurality of switching patterns includes an upper portion having a first width and a lower portion having a second width, and
wherein the first width is greater than the second width.

2. The semiconductor memory device of claim 1, wherein each of the plurality of switching patterns has an inverted triangle shape or an inverted trapezoid shape.

3. The semiconductor memory device of claim 1, wherein each of the plurality of switching patterns includes a transition metal oxide.

4. The semiconductor memory device of claim 1, wherein the isolating dielectric layer includes an insulator that does not contain oxygen.

5. The semiconductor memory device of claim 1, wherein the isolating dielectric layer includes a silicon nitride-based insulator.

6. The semiconductor memory device of claim 1, wherein:
upper surfaces of the plurality of switching patterns and an upper surface of the isolating dielectric layer are co-planar, and
lower surfaces of the plurality of switching patterns and a lower surface of the isolating dielectric layer are co-planar.

7. The semiconductor memory device of claim 1, wherein:
the lower electrode and the upper electrode include a metal nitride, and
the oxygen reservoir layer includes tantalum oxide.

8. The semiconductor memory device of claim 1, further comprising:
a lower contact plug between the lower interconnection line and the lower electrode; and
an upper contact plug between the upper electrode and the upper interconnection line.

9. The semiconductor memory device of claim 1, further comprising:
a spacer on side surfaces of the variable resistance layer and the oxygen reservoir layer,
wherein the spacer includes a silicon nitride layer.

10. The semiconductor memory device of claim 9, wherein the spacer covers a portion of an upper surface of the upper electrode.

11. A method for fabricating a semiconductor memory device, comprising:
forming a lower electrode material layer;
forming an isolating dielectric material layer over the lower electrode material layer, the isolating dielectric material layer including a plurality of pin holes each having an average pin hole width;
forming a plurality of wide holes each having an average wide hole width by widening the pin holes;
forming a variable resistance material layer by forming a plurality of switching patterns in the plurality of wide holes, the variable resistance material layer including the plurality of switching patterns and an isolating dielectric layer surrounding side surfaces of the plurality of switching patterns;
forming an oxygen reservoir material layer over the variable resistance material layer;
forming an upper electrode material layer over the oxygen reservoir material layer; and
forming an upper electrode, an oxygen reservoir layer, a variable resistance layer, and a lower electrode by patterning the upper electrode material layer, the oxygen reservoir material layer, the variable resistance material layer, and the lower electrode material layer.

12. The method of claim 11, wherein an average width of upper portions of the plurality of wide holes is greater than an average width of lower portions of the plurality of wide holes.

13. The method of claim 11, wherein the forming of the variable resistance material layer includes:
forming a switching material layer over the isolating dielectric material layer, the switching material layer filling the plurality of wide holes; and
forming the plurality of switching patterns by removing some of the switching material layer to expose the plurality of switching patterns and the isolating dielectric material layer.

14. The method of claim 13, wherein:
upper surfaces of the plurality of switching patterns and an upper surface of the isolating dielectric layer are co-planar, and
lower surfaces of the plurality of switching patterns and a lower surface of the isolating dielectric layer are co-planar.

15. The method of claim 11, wherein each of the plurality of switching patterns includes a transition metal oxide.

16. The method of claim 11, wherein the isolating dielectric material layer includes a dielectric material that does not contain oxygen.

17. The method of claim 11, wherein the isolating dielectric material layer includes silicon nitride.

18. The method of claim 11, further comprising:
conformally forming a spacer on side surfaces of the variable resistance layer and the oxygen reservoir layer,
wherein the spacer includes a silicon nitride layer.

19. The method of claim 18, wherein the spacer covers a portion of an upper surface of the upper electrode.

20. The method of claim 11, further comprising:
forming a lower contact plug between a lower interconnection line and the lower electrode; and
forming an upper contact plug between the upper electrode and an upper interconnection line.
